(19) United States
(12) Patent Application Publication
(10) Pub. No.: US 2011/0210756 A1
(43) Pub. Date: Sep. 1, 2011

(54) DEVICE FOR DETERMINING THE LENGTH OF A SET OF BORING RODS

(75) Inventors: Anton Scheibelmasser, Graz (AT); Abdelrhani Lamik, Kapfenberg (AT); Bouchra Lamik-Thonhauser, St. Peter-Freienstein (AT); Werner Lindner, Kapfenberg (AT); Robert Karpf, Bruck/Mur (AT)

(73) Assignee: ADVANCED DRILLING SOLUTIONS GMBH, Leoben (AT)

(21) Appl. No.: 13/127,131

(22) PCT Filed: Jun. 8, 2010
(86) PCT No.: PCT/AT2010/000200

§ 371 Date: May 2, 2011

(30) Foreign Application Priority Data
Jun. 8, 2009 (AT) A 883/2009

(51) Int. Cl. G01R 27/26; G01R 27/28

(52) U.S. Cl. 324/686; 324/649

(57) ABSTRACT

A device for detecting the length of a drilling column that has a plurality of pipes (1) assembled on couplings (2) is characterized in that on the pipes (1), there is at least one electrical line (3, 4) that is galvanically connected to the couplings (2). On one end of the electrical line (3, 4), there is a means (7) for the feed of electrical pulses into the electrical line (3, 4) and for detecting the propagation time of the electrical pulses from the means (7) to a reflection site on the other end (5) of the electrical line (3, 4) and back.

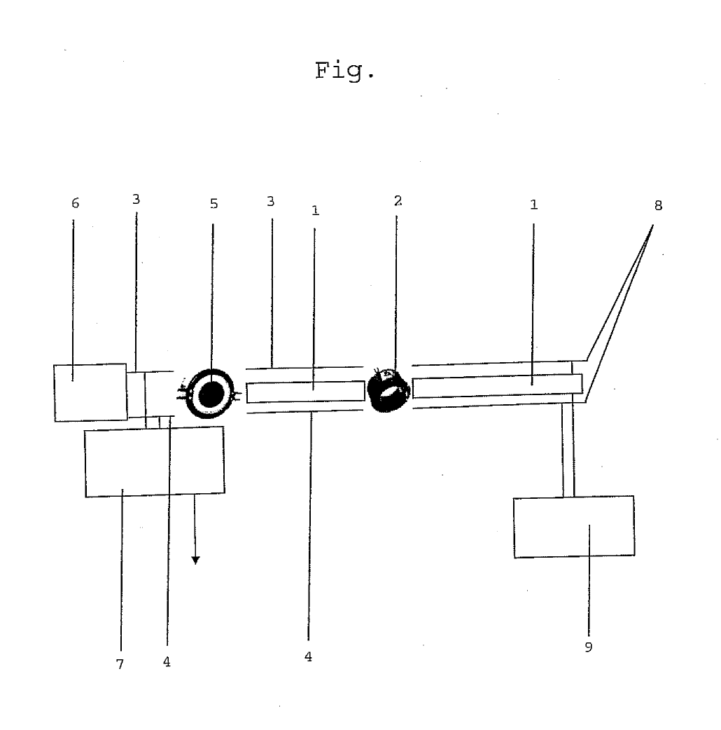

The invention relates to a device for detecting the length of a drilling column that has a plurality of pipes assembled on couplings.

One important measured quantity within the framework of deep wells in the petroleum and natural gas industry is the depth of the drill hole. It is found from the current position of the drill block and the sum of the lengths of the installed pipes and equipment.

Currently, the depth is determined semiautomatically. The block position is detected automatically. Conversely, each pipe installed in the drilling column is noted manually by operators. This often results in faults due to the pipes being entered incorrectly or not at all.

The problem of automatic detection of depth consists mainly in automatic recording of the installed pipes. As a result of mechanical/thermal stress on the pipes, the use of RFIDs, for example, is a problem. Optical recording methods (for example, a bar code) are precluded due to the fouling of the pipe.

Therefore, the object of the invention is to make available a device with which the length of the drilling column can be easily and reliably detected.

This object is achieved in a device of the initially mentioned type in that on the pipes, there is at least one electrical line that is galvanically connected to the couplings, on one end of the electrical line there being a means for the feed of electrical pulses into the electrical line and for detecting the propagation time of the electrical pulses from the means to a reflection site that is located, for example, on the other end of the electrical line and back.

In the device according to the invention, so-called time domain reflectometry is used that has been employed for a long time for detecting the length of cables. In this case, short rectangular electrical pulses are applied to the line, and reflections on the cable are detected. Depending on the terminating resistance (no load, short circuit, matching or mismatch), echoes occur from whose time behavior (propagation time) the distance to the cable end or to a defect site can be deduced. The prerequisite for the exact determination of the location is constant propagation times in the cable. They dictate constant cable properties (dielectric). The method is often used to look for line breaks or cable pinches. Also, it is already in use in the petroleum industry for these purposes.

The invention is based on pipes that are equipped, for example, with an at least two-pole electrical cable or alternatively with a coaxial cable.

One preferred embodiment of the invention is characterized in that the line of a pipe is galvanically connected to the line of a following pipe at the transition point to the coupling, and in that the surge impedance of the transition points is matched to the surge impedance of the line, and is preferably essentially the same. Because the surge impedance of the line in the individual pipes and the surge impedance of the transition points are known or constant, there is a constant known relationship between, on the one hand, the length of the drilling column and the cable length and, on the other hand, the propagation time of electrical pulses through the cable, from which the length of the cable and subsequently of the drilling column can be computed.

All pipes are preferably equipped with the same cable (same surge impedance). The geometrical structure of the pipe connections and couplings between the pipes and the transition points of the electrical line to the couplings is likewise always the same (same surge impedance); this greatly simplifies the computation of the length from the propagation time.

Since the distance from the last cabled pipe to the drilling head is constant and likewise known, the length of the drilling column from the feed site of the electrical signals to the tip of the drilling head can therefore be easily computed. Thus, using the invention, the length of the drill string or the depth of the drilling head can be automatically detected by way of the cable length that is changed by the pipes that are added or removed.

In order to be able to definitively deduce the total cable length, on the end of the line there must be a reflection site for the electrical signals, for example in the form of a mismatch. The latter is present, for example, in the form of a line that is open on the end in the case of the cabled and galvanically connected pipes. The incoming wave is strongly reflected by this open cable end and can be definitively detected at the cable start or feed site of the electrical signal. By means of the measured propagation time, the position of the reflection site can be deduced based on the known propagation velocity in the cable.

Since the propagation velocity depends mainly on the cable dielectric, it must be constant (same cable, same quality). Since the propagation velocity is a function mainly of the cable dielectric, it must be constant (same cable, same quality). Since the cable dielectric is dependent on temperature, the temperature constitutes an important variable. By introducing a depth-dependent correction factor, the effect of temperature on the dielectric can be compensated with increasing depth. This correction factor can be assumed to be a constant value. It can also be determined, however, by temperature measurements in the drill string. This can be advantageous since the temperature of the cable depends not only on the depth (roughly 3° C./100 m) and the geological properties of the formation, but mainly on the temperature of the drilling fluid. The latter, however, changes due to the above-described variables or as dictated by different flow rates. Most advantageously, the temperature is measured by measurement stations along the cable, and the temperature behavior is considered in the depth correction. In the case of the cabled drill string, a distribution of the measurement systems along the drill string is preferred. They can also measure the cable temperature in addition to data that are relevant to drilling. Knowledge of the temperature path of the cable dielectric is also important for these correction methods.

Since the pipes of the drilling column are galvanically connected at regular intervals (for example, 9 m or 15 m), a few hundred transition points for wave propagation are formed in the drilling column. In order to avoid an adverse effect of these transition points in the surge impedance (for example, reflections), the galvanic connection between the pipes is preferably made geometrically and electrically such that no impact occurs in the surge impedance (matching to the surge impedance of the line) and thus the recognition of the primary reflection on the end of the line is not hindered or changed.

The electrical consumers that are present in all cases in the drilling column string likewise constitute a transition point in the surge impedance for this method and can likewise be matched to the surge impedance of the line by electrical measures. One additional possibility consists in placing the consumer at the tip of the drilling column. In this case, a mismatch to the surge impedance of the line that is as large as possible must be produced.

Matchings of the surge impedance (AC voltage resistance) are easily possible when the supply line is operated with DC voltage (for example, 400 V DC). For example, a suitable capacitor that is connected in parallel to the consumer does not disrupt operation of the DC consumer, but for high frequency constitutes a short circuit and implements an extreme mismatch.

The pulses are fed into the turning drill string during the drilling process by means of slip rings in a so-called swivel, a pivoted part on the top end of the drill string for the feed of rinsing fluid, but also electrical energy and communication. Since, during the round trip of the column, the swivel is not connected due to the process, the feed can take place directly galvanically by a plug that can be mounted on the so-called elevator link, one part of a hoisting device that is used for the round trip of the drill string.

In order to avoid disrupting HF communication that may be underway with devices in the drilling column or drilling head, the depth measurement should preferably be synchronized with the data transmission (for example, master/slave) since isolation of the reflected electrical signals could otherwise be difficult or impossible.

The invention can eliminate the manual input of pipes and their length since the depth can be deduced by means of propagation time measurement. Commercial reflectometers can be used and can function as a measurement device. The measured value need be corrected only by one offset to the drilling head or by a correction factor (pipe length/cable length). Since the cable expands simultaneously with the pipe, this change in length is recognized in the propagation time measurement.

In the invention, at the same time, one side effect is also quality control of the cabled drilling column. Defective connection sites or line interruptions are optically detected on the oscilloscope in servicing or in operation by suddenly incorrect depth measurement values. The location of the defect can be deduced by the propagation time.

One important aspect in the use of cabled, galvanically connected drilling columns is the reliability of the connection between the pipes. Using the invention, the quality of the connection can be immediately checked after the conductive connection is established (for example, interruption, short circuit).

Other preferred embodiments of the invention are the subject matter of the other dependent claims.

One preferred embodiment of the invention is described in more detail below with reference to the attached drawings in which a device according to the invention on a drilling column is schematically shown.

Two pipes are symbolically numbered 1 in the drawings; they are connected to one another using a coupling 2. A drilling column consists of a plurality of these pipes 1 that are connected to one another using couplings 2 and of a drilling head that is not shown in the drawings and that is attached to the end of the last pipe 1, which end is the right one in the drawings. The line phases of a two-pole electrical line are labeled 3 and 4. The line phases 3, 4 are connected to a power supply 6 on one end via a slip ring 5, and the power supply transforms the grid AC voltage into, for example, 400 V DC voltage.

A means 7 for the feed of electrical pulses into the line phases 3 and 4 of the electrical line is connected between the power supply 6 and the slip ring 5 and detects the propagation time of the electrical pulses from the means 7 or the feed site into the line phases 3 and 4 to a reflection site on the other end 8 of the electrical line 3, 4 and back.

On the other end 8 of the line that is shown at the right in the drawings, an electrical consumer 9 can be connected that is supplied with current from the power supply 6. When the electrical consumer 9 at the same time is to form the reflection site for the electrical pulses that are fed from the means 7, it must be made such that it constitutes a so-called defect site at which the signals are reflected. Alternatively, it is also possible for the electrical consumers 9 to be located somewhere on the path between the feed site and the end 8 of the line 3, 4, and in this case, care must be taken that the connection of the electrical consumer 9 does not constitute a defect in order not to adversely affect the propagation time measurement of the electrical signals. If there is not a consumer 9 that constitutes a defect on the end 8 of the line 3, 4, the open end of the line 3, 4 forms the defect on which the signals are reflected.

Instead of the two-pole electrical cable 3, 4 that is shown in the drawings, in addition or alternatively, for example, a coaxial cable or another measurement line can be used that is used without connection of a power supply 6 and an electrical consumer 9, for example, only for measuring the length of the drilling column.

Since the propagation time of the electrical signals in the line 3, 4 increases with each additional pipe 1 and each additional coupling 2, using the change of the propagation time, the length of the drilling column, specifically of the line 3, 4, can be definitively computed, optionally with consideration of additional lengths such as the length between the feed site of the electrical signals and the slip ring as well as the distance from the end 8 of the line 3, 4 to the drilling head that is not shown in the drawings.

In order to enable an optimum measurement, the following measures are recommended:
Matching of the pipe connections to the surge impedance of the line (connection free of reflection);
Matching of consumers along the line to the surge impedance (connection free of reflection);
Generating a mismatch on the end of the measured distance generally on the end of the line (primary reflection);
Mechanical connection of cable and drilling column and cabling of the pipes with constant cable length;
Compensation of the material influences on the propagation time measurement (for example, temperature dependency of the electrical properties of the cable (dielectric));
Synchronization of the propagation time measurement with the HF communication on the line.

By using different cable types, cable cross-sections or diverse electrical connectors (slip rings, cable drums, etc.), geometrical matching to the surge impedance cannot be possible from case to case for mechanical reasons (lack of space in the mechanical connector). In this case, matching the connectors to the line by an electrical network (T circuit, H circuit, pi circuit) with discrete electrical components (matching network) can be achieved. Since these matching networks likewise consume electrical energy, an independent measurement line can alternatively be installed that does not use the energy supply.

The electrical consumers that are present along the drill string for the measurement method that is preferably to be used in the invention likewise constitute a transition point in the surge impedance and are matched to the surge impedance of the line by electrical measures. For this purpose, transformation networks can be built up from discrete electrical consumers that match the impedance of the consumer to the surge impedance of the line.

1. Device for detecting the length of a drilling column that has a plurality of pipes (1) assembled on couplings (2), characterized in that on the pipes (1), there is at least one electrical line (3, 4) that is galvanically connected to the couplings (2), on one end of the electrical line (3, 4) there being a means (7) for the feed of electrical pulses into the electrical line (3, 4) and for detecting the propagation time of the electrical pulses from the means (7) to a reflection site that is located, for example, on the other end (5) of the electrical line (3, 4) and back.

2. Device according to claim 1, wherein the line (3, 4) of a pipe (1) is galvanically connected to the line (3, 4) of a following pipe (1) at a transition point to the coupling (2), and wherein the surge impedance of the transition points is matched to the surge impedance of the line (3, 4), and is preferably essentially the same.

3. Device according to claim 1, wherein the line (3, 4) is a supply line for electrical consumers (9) in the drilling column and/or in a drilling head.

4. Device according to claim 3, wherein the supply line (3, 4) is operated with DC voltage of preferably 400 V.

5. Device according to claim 1, wherein the reflection site is an open line end (8).

6. Device according to claim 1, wherein the reflection site is an electrical consumer (9).

7. Device according to claim 1, wherein a capacitor is connected preferably parallel to a consumer (9).

8. Device according to claim 1, wherein the electrical pulses are rectangular pulses.

9. Device according to claim 1, wherein the means (7) is connected to the end of the drilling column via a slip ring (5).

10. Device according to claim 1, characterized by a control that separates a data communication in time through the line (3, 4) from the sending of pulses and the measurement of the propagation time.

11. Device according to claim 2, wherein the line (3, 4) is a supply line for electrical consumers (9) in the drilling column and/or in a drilling head.
